(19) United States
(12) Patent Application Publication
(10) Pub. No.: US 2016/0208408 A1
(43) Pub. Date: Jul. 21, 2016

(54) UPPER HEAT SHIELDING BODY, INGOT GROWING APPARATUS HAVING THE SAME AND INGOT GROWING METHOD USING THE SAME

(71) Applicant: LG SILTRON INC., Gyeongsangbuk-do (KR)

(72) Inventors: Jin-Kyu Sung, Gyeongsangbuk-do (KR); II-Su CHOI, Gyeongsangbuk-do (KR); Do-Yeon KIM, Gyeongsangbuk-do (KR)

(21) Appl. No.: 14/915,159

(22) PCT Filed: Aug. 19, 2014
(86) PCT No.: PCT/KR2014/007655

§ 371 Date: Feb. 26, 2016

(30) Foreign Application Priority Data
Aug. 27, 2013 (KR) 10-2013--0101682

(51) Int. Cl. C30B 15/20; C30B 15/30; C30B 29/06; C30B 15/14

(52) U.S. Cl. CPC C30B 15/20; C30B 15/14; C30B 15/30; C30B 29/06

(57) ABSTRACT

Provided is an ingot growing apparatus. The ingot growing apparatus for growing an ingot from a silicon melt received in a crucible by using a seed includes a chamber providing a space in which a series of processes for growing the ingot is performed, the crucible disposed within the chamber, a heating unit disposed outside the crucible, a seed chuck fixing the seed, an elevation unit connected to the seed chuck; and an upper heat shielding body disposed above the crucible, the upper heat shielding body having a hole through which the grown ingot passes, wherein the hole is adjustable in size.

### TECHNICAL FIELD

The present disclosure relates to an ingot growing apparatus and method for producing a single crystal silicon ingot.

### BACKGROUND ART

Silicon single crystal wafers used as materials of semiconductor devices are manufactured by slicing a single crystal ingot that is manufactured by using a czochralski (CZ) method.

A method for growing a silicon single crystal ingot by using the CZ method includes a dipping process in which polycrystal silicon is melted in a quartz crucible, and then a seed is dipped into the silicon melt, a necking process in which the seed is pulled to grow a thin and long crystal, and a shouldering in which the crystal is grown in a diameter direction to produce a crystal having a target diameter.

Thereafter, a body growing process in which the silicon single crystal ingot having a predetermined diameter is grown to a desired length and a tailing process in which the single crystal ingot gradually decreases in diameter to separate an ingot from the silicon melt may be performed to grow the silicon single crystal ingot.

However, when seed contacts the silicon melt, a lower end of the seed that is in contact with the silicon melt may significantly increase in temperature up to a temperature of a surface of the silicon melt to apply a thermal shock on the lower end of the seed.

Also, shear stress may be applied to the seed due to the thermal shock to cause a dislocation on a portion of the seed that is in contact with the silicon melt. The dislocation occurring on the portion of the seed that is in contact with the silicon melt may be propagated to the lower portion of the seed when the crystal is grown. As a result, the dislocation may have a bad influence on the growth of the single crystal.

Thus, to prevent the dislocation from being propagated into the single crystal, a dash necking process has been performed in an initial single crystal manufacturing process.

The dash necking process may be a technology in which a single crystal is withdrawn in a thin and long shape to remove the dislocation. In general, the single crystal (a necking part) grown in the necking process may have a diameter of about 3 mm to about 5 mm.

If the necking part has a diameter exceeding about 5 mm, shear stress generated by a temperature difference between the inside and the outside of the necking part may significantly increase. As the shear stress increases, a propagation rate of the dislocation may be greater than a pulling speed of the single crystal in the necking part. Thus, the dislocation generated in the lower end of the crystal of the seed may not be removed. The dash necking process may be a positive effect in that the dislocation is capable of being removed. However, in view of the seed that supports the single crystal having a high weight, the dash necking process may affect a negative effect.

That is, since a load of the single crystal is applied to the necking part that has the thin and long shape to remove the dislocation, the single crystal may fall down due to broken of the necking part.

Also, the single crystal having a diameter of about 450 mm at present is expected to reach a weight of about 1 ton in the late process. Thus, there is a limitation in which a necking part having a diameter of about 3 mm to about 5 mm does not support the single crystal having a weight of about 1 ton.

Thus, a technology that is capable of growing a large-caliber single crystal without performing the necking process is required.

As semiconductor technologies are being developed in recent years, a single crystal silicon ingot becomes high weight and large caliber. Thus, a silicon raw material may increase in size, and thus it may be necessary to stack more amount of polysilicon in a crucible.

As a result, a heater power for heating the polysilicon may increase. Therefore, the ingot may increase in price due to the increase in the heater power, and also, dislocation generation in the single crystal may increases, or product yield may be deteriorated while the single crystal is grown.

### DISCLOSURE

### Technical Problem

Embodiments provides an ingot growing apparatus and method by which a heat loss is reduced, and a necking part increases in diameter to produce a large-caliber ingot without generating dislocation when an ingot is produced.

### Technical Solution

In one embodiment, an ingot growing apparatus for growing an ingot from a silicon melt received in a crucible by using a seed includes: a chamber providing a space in which a series of processes for growing the ingot is performed; the crucible disposed within the chamber; a heating unit disposed outside the crucible; a seed chuck fixing the seed; an elevation unit connected to the seed chuck; and an upper heat shielding body disposed above the crucible, the upper heat shielding body having a hole through which the grown ingot passes, wherein the hole is adjustable in size.

In another embodiment, an ingot growing method includes: receiving polycrystal silicon in a crucible; dosing a hole of an upper heat shielding body disposed above the crucible; heating the crucible to form a silicon melt; opening the hole of the upper heat shielding body by a predetermined size so that a seed passes through the hole to allow the seed to pass through the hole of the upper heat shielding body; increasing the hole size of the upper heat shielding body according to an expansion in diameter of an ingot while growing the ingot by using the seed; forming the hole of the upper heat shielding body with a size greater by a predetermined size than that of a body while performing a body growing process for forming the body by using the seed; and performing a tailing process by using the seed.

### Advantageous Effects

According to the proposed embodiment, the hole size adjustment unit may be mounted within the upper heat shielding body to minimize the thermal shock generated when the seed is dipped into the silicon melt, thereby increasing the diameter of the necking part.

Also, the large-caliber single crystal silicon ingot may be stably produced by using the necking part having the increasing diameter.

Also, according to the current embodiment, when the silicon melt is heated, the heater power may be reduced to improve quality of the single crystal silicon ingot and reduce manufacturing costs.

Also, according to the current embodiment, a temperature of the outer portion of the ingot may be precisely controlled to restrict the defects of the ingot, thereby improving the quality of the ingot.

### DESCRIPTION OF DRAWINGS

FIG. 1 is a schematic view of an ingot growing apparatus including an upper heat shield of which a hole size is adjustable according to an embodiment.

FIG. 2 is a cross-sectional view of the upper heat shielding body of which the hole size is adjustable according to an embodiment.

FIG. 3 is a view of a state in which a driving unit transmits a power to a hole size adjustment unit according to an embodiment.

FIG. 4 is an exploded perspective view of the hole size adjustment unit according to an embodiment.

FIG. 5 is a view of a state in which a portion of a hole of the upper heat shielding body is dosed according to an embodiment.

FIG. 6 is a view of a state in which the hole of the upper heat shielding body is opened according to an embodiment.

FIG. 7 is a flowchart illustrating a method of growing an ingot by using the ingot growing apparatus including the upper heat shielding body according to an embodiment.

### MODE FOR INVENTION

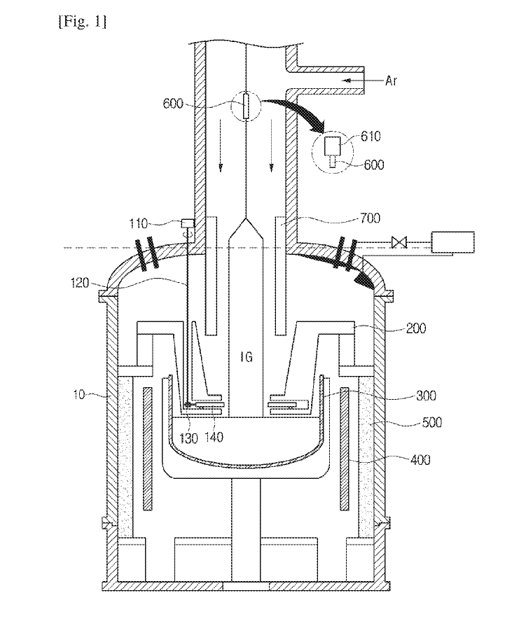

Hereinafter, exemplary embodiments will be described in detail with reference to the accompanying drawings. The technical scope of the embodiments will fall within the scope of this disclosure, and addition, deletion and modification of components or parts are possible within the scope of the embodiments. FIG. 1 is a schematic view of an ingot growing apparatus including an upper heat shield of which a hole size is adjustable according to an embodiment.

Referring to FIG. 1, an ingot growing apparatus according to an embodiment may include a chamber 10, a crucible 300 receiving a silicon melt, a seed chuck 610 fixing a seed 600 for pulling an ingot in the silicon melt, an elevation unit (not shown) connected to the seed chuck 610 to elevate and rotate the seed chuck 610, a heating unit 400 heating the crucible 300, a side heat shielding body 500 disposed on a side surface of the heating unit 400 to shield heat, an upper heat shielding body 200 shielding heat of the silicon melt, a hole size adjustment unit 140 mounted inside the heat shielding body to adjust a hole size, a driving unit 110 operating the hole size adjustment unit 140, a water cooling tube 700 cooling the ingot grown on the upper heat shielding body 200, and a control unit 800 controlling an overall process of an ingot growing process in addition to the driving unit 110.

The chamber 10 provides a space in which predetermined processes for growing an ingot for a wafer used as materials of electronic components such as semiconductors are performed.

The crucible 300 in which the silicon melt as a hot zone structure may be disposed in the chamber 10. A support structure and a support for supporting a load may be coupled to a lower portion of the crucible 300.

A rotation driving device may be mounted on the support. Thus, the crucible 300 may rotate and be elevated.

Also, the seed chuck 610 fixing the seed 600 for growing the ingot from the silicon melt within the crucible 300 may be disposed above the crucible 300. The seed chuck 610 may vertically move and rotate by the elevation unit disposed in an upper portion of the chamber 10.

That is, the elevation unit may vertically move the seed chuck 610 to dip the seed 600 into the silicon melt, and then lift the seed 600 while rotating to grow the ingot.

A heating unit 400 supplying heat energy to melt polysilicon may be disposed outside the crucible 300. The side heat shielding body 500 for shielding heat of the heating unit 400 to prevent the heat from being released to the outside of the chamber 10 may be disposed outside the heating unit 400.

Also, the upper heat shielding body 200 having a hole through which the ingot grown in the silicon melt passes and shielding heat released from the silicon melt may be defined in an upper portion of the crucible 300.

While the ingot is grown, if the hole of the upper heat shielding body 200 is adjustable in size, there is a huge advantage.

For example, when the polysilicon is melted, the hole may be fully dosed to block the heat released upward from the crucible 300. Also, while a dipping process for dipping the seed 600 is performed, the hole may have a sufficient size to allow the seed 600 to pass therethrough. Also, the seed 600 may be disposed between the silicon melt and the upper heat shielding body 200 and then be dipped after being heated to reduce thermal shock occurring when the seed 600 is dipped into the silicon melt.

Thus, due to the reduction of the heat shock, an occurrence of dislocation may be restricted to increase a diameter of a necking part. As a result, a high-weight large-caliber ingot may be grown by using the necking part having the increased diameter. For example, the ingot growing apparatus according to the current embodiment may stably produce an ingot having a diameter of about 450 mm or more.

Also, while a body growing process is performed, the hole may have a size that reaches a diameter of a body to block the heat of the silicon melt against the outside, thereby reducing the heat loss. In addition, the ingot may be cooled outside the upper heat shielding body 200.

Thus, the upper heat shielding body 200 according to the current embodiment may further include the hole size adjustment unit 140 for adjusting the hole size, the driving unit 110 connected to the hole size adjustment unit 140 to operate the hole size adjustment unit 140, and the control unit 800 for controlling the driving unit 110.

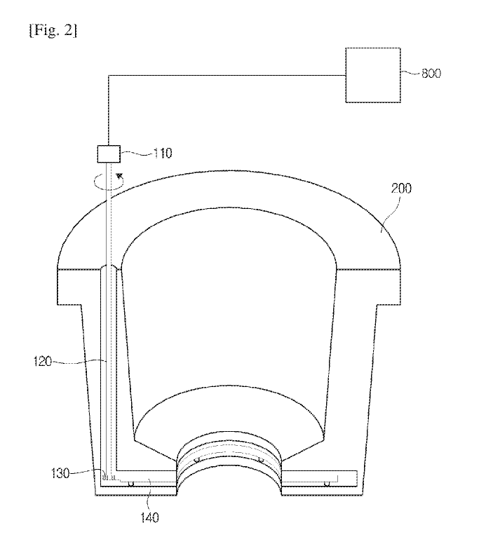

The hole size adjustment unit 140, the driving unit 110, and the control unit 800 will be described in more detail with reference to FIG. 2.

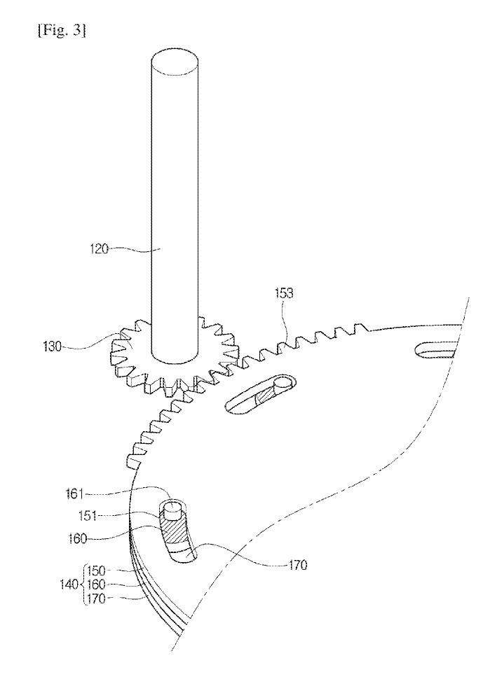

FIG. 2 is a cross-sectional view of the upper heat shielding body 200 of which the hole size is adjustable, and FIG. 3 is a view of a state in which the hole size adjustment unit 140 operates by the driving unit 110.

Referring to FIGS. 2 and 3, a gear shaft 120 for transmitting a power to the hole size adjustment unit 140 is coupled to the driving unit 110 within the upper heat shielding body 200, and a gear 130 receiving the power from the gear shaft 120 to rotate is coupled to the hole size adjustment unit 140.

In more detail, a groove in which the hole size adjustment unit 140 is inserted may be defined along a side surface of the hole through which the ingot passes in the upper heat shielding body 200. The hole size adjustment unit 140 may be mounted in the groove.

Also, the gear may be disposed on a side of an outer circumference surface of the hole size adjustment unit 140 and connected to the hole size adjustment unit 140.

The gear shaft 120 may extend upward from the gear 130 and be coupled to the driving unit 110. That is, a vertical path in which the gear shaft 120 is disposed may be provided in the upper heat shielding body 200.

That is, when the driving unit 110 disposed outside the upper heat shielding body 200 rotates the gear shaft 120, the gear 130 coupled to a lower end of the gear shaft 120 may rotate. Here, the hole size adjustment unit 140 engaged with the rotating gear 130 may receive a power to operate. The series of operations may be controlled by the control unit 800 connected to the driving unit 110.

The control unit 800 may be separately provided to adjust the hole size. Alternatively, the control unit 800 may serve as a central controller for controlling an overall process of the ingot growing process.

FIG. 4 is an exploded perspective view of the hole size adjustment unit according to an embodiment.

An operation of the hole size adjustment unit 140 will be described in detail with reference to FIG. 4. The hole size adjustment unit 140 may perform an operation similar to that of an aperture of a general camera.

For example, the hole size adjustment unit 140 may include a plurality of blade parts 160 for opening or dosing the hole of the upper heat shielding body 200, a rotation plate 150 disposed above the blade parts 160 to shaft-rotate the blade parts 160, and a board 180 disposed under the blade parts 160 to support the blade parts 160. Holes 152, 163, and 182 through which the ingot grown in a ring shape passes may be defined in central portions of the rotation plate 150, the blade parts 160, and the board 180, respectively.

Gear grooves 153 may be defined along a circumferential surface of the rotation plate 150 and engaged with tooth of the gear 130 to receive the power from the gear 130. As the gear 130 rotates, the rotation plate 150 may rotate by using centers of the holes 152, 163, and 182 as an axis.

Also, the rotation plate 150 may be rotatably slipped and supported on the blade parts 160. A plurality of cam holes 151 may be defined with the same interval along an outer circumference of the rotation plate 150. A driving pin 161 protruding from a top surface of each of the blade parts 160 may be hung and fitted into each of the cam holes 151.

Thus, as the rotation plate 150 rotates, the driving pins 161 may respectively move within the cam holes 151, and each of the blade parts 160 may shaft-rotate with respect to an shaft hole 162 (a hinge hole) defined in an end thereof.

That is, the shaft hole 162 that serves as a hinge axis may be defined in the end of each of the blade parts 160. Also, the driving pin 161 for receiving the power from the rotation plate 150 may be disposed on a side of the top surface of each of the blade parts 160.

Also, since the shaft hole 162 is coupled to the support shaft 181 that protrudes from the board 180 to support the blade parts so that the blade parts 160 shaft-rotates, each of blade parts 160 may be rotatably slipped above the board 180 by using the shaft hole 162 as a rotation axis.

Thus, when the rotation plate 150 rotates to move the driving pin 161 disposed in the cam hole 151, the blade parts 160 may rotate. As a result, a portion of the blade parts 160 may be selectively disposed in the hole of the upper heat shielding body 200 or the groove of the upper heat shielding body 200 according to a rotation direction thereof to adjust a size of each of the holes 152, 163, and 182 of the upper heat shielding body 200.

Each of components of the hole size adjustment unit 140 will now be described in detail. At least three blade parts 160 may be provided. Here, if the number of blade parts 160 increases, each of the holes 152, 163, and 182 may be more precisely adjusted in size when the holes 152, 163, and 182 are opened or dosed. Thus, it is advantageous to provide at least six blade parts 160 in view of hole size adjustment and design structure.

Also, since a portion of the blade parts 160 has to block the heat of the silicon melt when the blade parts 160 are disposed in the holes 152, 163, and 182 of the upper heat shielding body 200, each of the blade parts 160 may be formed of a material having high reflectivity and high-temperature resistance and that does not contaminate the silicon melt.

For example, each of the blade parts 160 may be formed of high-purity quartz, graphite, or high-purity carbon composite (M/I 1.0 ppma or less). Also, a surface of each of the blade parts 160 may be coated with pyrolytic graphite having high reflectivity.

That is, the blade parts 160 may be provided in plurality. Also, the shaft hole 162 may be defined in the end of each of the blade parts 160, and the driving pin 161 may be disposed on a side of the top surface of each of the blade parts 160. Each of the blade parts 160 may be formed of a high-purity carbon material.

Also, the rotation plate 150 has the cam groove 160 having the same number as the blade parts 160. Here, the driving pin 161 may be hung and fitted into the cam groove 160. A gear groove corresponding to the gear 130 may be defined in at least one section of the rotation late 150 along an outer circumferential surface of the rotation plate 150. Also, at least one hook part 154 for successively fixing the rotation plate 150, the blade parts 160, and the board 180 may be disposed on an edge of the rotation plate 150.

Also, a hook groove in which the hook 154 of the rotation plate 150 is hung and fitted is defined in an outer circumference of the board 180. The support shaft 181 corresponding to the shaft hole 162 of the blade part 160 may be disposed on a top surface of the board 180 so that the blade parts 160 are rotatably slipped and supported.

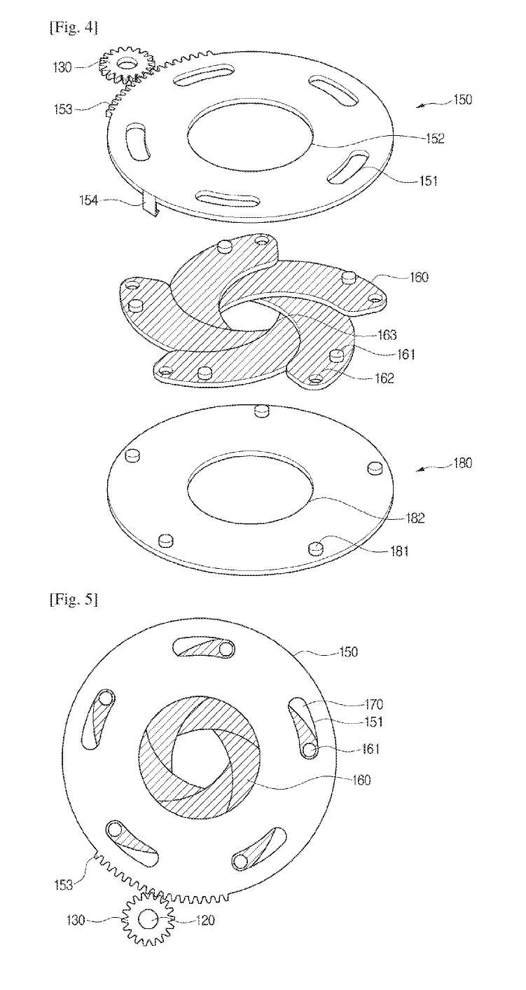

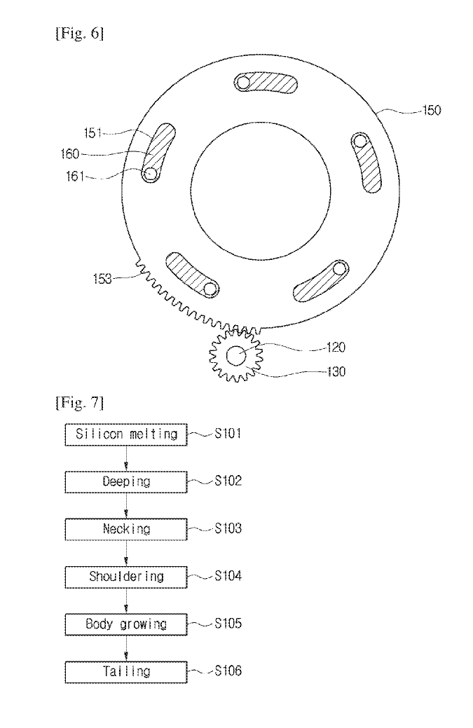

FIG. 5 is a view of a state in which the hole of the upper heat shielding body 200 is reduced in size, and FIG. 6 is a view of a state in which the hole of the upper heat shielding body 200 is opened.

Referring to FIG. 5, a portion of the blade part 160 is disposed in the hole of the upper heat shielding body 200 to reduce the size of the hole. If when the blade part 160 further rotates by the driving part 110, the hole may be fully dosed. That is, a dosed degree of the hole may be adjusted according to a rotating degree of the gear shaft 120 by the driving unit 110.

Referring to FIG. 6, all blade parts 160 may be disposed in the grooves of the upper heat shielding body 200 to fully open the hole of the upper heat shielding body 200. The driving unit 110 may rotate in a direction in which the hole of the rotation plate 150 is dosed to locate the blade parts 160 in the grooves, thereby opening the hole.

That is, the driving unit 110 may adjust the rotation direction and rotating degree of the gear shaft 120 to control the upper heat shielding body 200 and the hole size adjustment unit 140, thereby adjusting the hole size of the upper heat shielding body 200.

A process of producing a single crystal silicon ingot by using the above-described components will be described with reference to FIG. 7.

FIG. 7 is a flowchart illustrating a method of growing the ingot by using an ingot growing apparatus including the upper heat shielding body 200.

In the ingot growing process that will be described below, a hole size of the upper heat shielding body 200 is controlled by a control unit 800.

First, a polycrystal silicon may be filled into the crucible 300, and then the hole of the upper heat shielding body 200 may be fully dosed by the hole size adjustment unit 140.

That is, the driving unit 110 rotates the gear shaft 120 to allow the blade parts 160 of the hole size adjustment unit 140 to fully dose the hole of the upper shielding body 200.

Thereafter, the heating unit 400 heats the crucible 300 to melt the polycrystal silicon. Here, an upper portion of the crucible 300 may be fully dosed by the upper heat shielding body 200 to reduce a heat loss of the heating unit 400 (S101).

Then, to perform a dipping process, the seed 600 and the seed chuck 610 descend by the elevation unit. The driving unit 110 operates the hole size adjustment unit 140 to open the hole of the upper heat shielding body 200 so that the seed 600 passes through the hole of the upper heat shielding body 200. The seed 600 may pass through the opened hole and then be disposed in a space between the silicon melt and the upper heat shielding body 200. Also, when the seed 600 is heated by heat transmitted from the silicon melt, and thus a temperature difference between the seed 600 and the silicon melt is sufficiently lowered, the seed 600 may further descend and then be dipped into the silicon melt.

Here, the seed between the upper heat shielding body 200 and the silicon melt may be heated at a temperature of about 1,000° C. or more, and more particularly, at a temperature of about 1,200° C. or more. As the temperature difference between the seed 600 and the silicon melt is lowered, the thermal stress may be reduced to prevent the dislocation from occurring by the thermal shock (S102).

Thereafter, a necking process is performed. In the current embodiment, the seed 600 may be dipped after being sufficiently heated at a temperature of about 1,200° C. so that the thermal shock of the necking part may be about 2.0 Mpa or less (particularly, 1.5 Mpa or less). Also, since the occurrence of the dislocation due to the thermal shock is restricted, although the necking part has a diameter of about 5.5 mm or more, dislocation free ingot may be produced.

Here, the elevation unit may maintain a pulling speed of the seed 600 to a speed of about 4.0 mm/min or less, and more particularly, a speed of about 2.0 mm/min (S103).

After the necking process is finished, a shouldering process for growing the crystal in a diameter direction to produce an ingot having a target diameter. Here, the driving unit 100 increases a hole size of the upper heat shielding body 200 according to an increase in a diameter of a shoulder part to minimize a heat loss of the silicon melt. Also, temperature gradient G of a solid-liquid interface may be controlled to restrict an occurrence of defects in the ingot (S104).

Thereafter, a body growing process may be performed. Thus, since the necking part increases in diameter to endure a high weight, a large-caliber body may be produced. For example, an ingot having a diameter of about 450 mm or more may be produced without using a separate device.

Here, the driving unit 110 may operate the hole size adjustment unit 140 to locate the blade part 160 at a position at which the hole has a size greater than a diameter of the ingot. Particularly, a distance between an outer portion of the ingot and the blade part 160 may be controlled to control the temperature gradient G of the solid-liquid interface. Also, the leakage of the heat of the silicon melt to the outside may be blocked to increase a cooling speed of the ingot at an upper side of the upper heat shielding body 200.

For example, to prevent the hole size adjustment unit 140 and the ingot from colliding with each other, the driving unit 110 may operate the hole size adjustment unit 140 so that the hole has a size greater by about 10 mm than a diameter of the ingot when the shouldering and body growing processes are performed. Here, the elevation unit may maintain the pulling speed of the seed 600 at a speed of about 0.3 mm/min to about 1.0 mm/min.

Schematically explaining the defects of the ingot, when the single crystal is grown, the silicon melt may be solidified and crystallized to cause vacancy-type and interstitial-type point defects. Then, as the ingot is continuously grown, a boundary of the ingot may be cooled, and thus, the vacancy-type and interstitial-type point defects may be combined with each other to form agglomeration, thereby causing the vacancy-type and interstitial-type point defects.

The above-described defects may be restrained by mainly using a method of controlling a ratio V/G that is a ratio of a pulling speed V of the single crystal to a temperature gradient G on the solid-liquid interface within a specific range. When the upper heat shielding body 200 is adjusted in hole size, the temperature gradient G may be precisely controlled to restrict the occurrence of the defects (S105).

Finally, a tailing process may be performed to produce a large-caliber high-quality ingot (S106).

In the ingot growing apparatus as described above, when the silicon melt is heated, the heat leaking from the silicon melt may be blocked to reduce the heat loss. Also, before the necking process is performed, the seed 600 may be heated to reduce the thermal shock, thereby increasing a diameter of the necking part. In addition, since the necking part increases in diameter, the large-caliber ingot may be more stably grown. Also, since the upper heat shielding body 200 precisely adjusts a temperature of the outer portion of the ingot, the high-quality ingot may be produced.

Accordingly, a person having ordinary skill in the art will understand from the above that various modifications and other equivalent embodiments are also possible.

### INDUSTRIAL APPLICABILITY

The embodiment provides the ingot growing apparatus for producing an ingot for a wafer, and thus, industrial usability is high.

1. An ingot growing apparatus for growing an ingot from a silicon melt received in a crucible by using a seed, the ingot growing apparatus comprising:
a chamber providing a space in which a series of processes for growing the ingot is performed;
the crucible disposed within the chamber;
a heating unit disposed outside the crucible;
a seed chuck fixing the seed;
an elevation unit connected to the seed chuck; and
an upper heat shielding body disposed above the crucible, the upper heat shielding body having a hole through which the grown ingot passes, wherein the hole is adjustable in size.

2. The ingot growing apparatus according to claim 1, wherein the upper heat shielding body comprises a hole size adjustment unit for adjusting a hole size of the upper heat shielding body.

3. The ingot growing apparatus according to claim 2, further comprising a driving unit for driving the hole size adjustment unit.

4. The ingot growing apparatus according to claim 3, wherein the hole size adjustment unit comprises:
a blade part constituted by a plurality of blade parts for opening or dosing a hole of the upper heat shielding body;
a rotation plate disposed above the blade parts to move the blade parts; and
a board disposed under the blade parts to support the blade parts.

5. The ingot growing apparatus according to claim 4, wherein a ring-shaped opening through which the grown ingot passes is defined in a central portion of each of the blade parts, the rotation plate, and the board.

6. The ingot growing apparatus according to claim 4, wherein at least portion of the blade parts is selectively disposed in the opening to adjust the hole size of the upper heat shielding body.

7. The ingot growing apparatus according to claim 4, wherein each of the blade parts is formed of one of high-purity quartz, graphite, and high-purity carbon composite.

8. The ingot growing apparatus according to claim 7, wherein a surface of each of the blade parts is coated with graphite.

9. The ingot growing apparatus according to claim 4, wherein a path is provided in the upper heat shielding body, a gear shaft connected to the driving unit is disposed in the path, a gear is disposed on an end of the gear shaft, and a gear groove engaged with the gear is defined in an outer circumferential surface of the rotation plate.

10. The ingot growing apparatus according to claim 9, wherein the driving unit rotates the gear shaft to gradually open or dose the hole of the upper heat shielding body.

11. The ingot growing apparatus according to claim 10, further comprising a control unit for controlling the hole size of the upper heat shielding body through the driving unit according to an ingot growing process.

12. A upper heat shielding body disposed within an ingot growing apparatus to shield heat of a crucible receiving a silicon melt against the outside, the upper heat shielding body comprising:
an insulation unit disposed above the crucible, the insulation unit having a hole through which an ingot passes;
a hole size adjustment unit mounted on the insulation unit to successively adjust a hole size of the insulation unit; and
a driving unit driving the hole size adjustment unit.

13. The upper heat shielding body according to claim 12, wherein the hole size adjustment unit comprises:
a blade part constituted by a plurality of blade parts for opening or dosing the hole of the insulation unit;
a rotation plate disposed above the blade parts to move the blade parts; and
a board disposed under the blade parts to support the blade parts.

14. An ingot growing method comprising:
receiving polycrystal silicon in a crucible;
dosing a hole of an upper heat shielding body disposed above the crucible;
heating the crucible to form a silicon melt;
opening the hole of the upper heat shielding body by a predetermined size so that a seed passes through the hole to allow the seed to pass through the hole of the upper heat shielding body;
increasing the hole size of the upper heat shielding body according to an expansion in diameter of an ingot while growing the ingot by using the seed;
forming the hole of the upper heat shielding body with a size greater by a predetermined size than that of a body while performing a body growing process for forming the body by using the seed; and
performing a tailing process by using the seed.

15. The ingot growing method according to claim 14, wherein the seed is heated at a temperature of about 1,200° C. before the seed is dipped so that thermal shock is below about 1.5 Mpa when the seed is dipped into the silicon melt.

16. The ingot growing method according to claim 14, wherein, when the body growing process is performed, the hole of the upper heat shielding body has a size greater by about 10 mm than a diameter of the body.

17. The ingot growing method according to claim 14, wherein, when the necking process is performed, the necking part has a diameter of about 5.5 mm or more.
